(19) United States
(12) Patent Application Publication
(10) Pub. No.: US 2025/0211223 A1
(43) Pub. Date: Jun. 26, 2025

(54) SEMICONDUCTOR DEVICE, ELECTRONIC DEVICE AND VEHICLE

(71) Applicant: ROHM CO., LTD., Kyoto-shi (JP)

(72) Inventors: Joita ADRIAN, Kyoto-shi (JP); Kenji MURAOKA, Kyoto-shi (JP)

(21) Appl. No.: 19/078,061

(22) Filed: Mar. 12, 2025

Related U.S. Application Data
(63) Continuation of application No. PCT/JP2023/027789, filed on Jul. 28, 2023.

(30) Foreign Application Priority Data
Sep. 12, 2022 (JP) 2022-144311

(51) Int. Cl. H03K 17/082; H03K 17/08

(52) U.S. Cl. CPC H03K 17/0822; H03K 2017/0806

(57) ABSTRACT

A semiconductor device includes an output switch, an overcurrent protection circuit which detects an output current flowing through the output switch to perform overcurrent protection, an overheat protection circuit which detects a temperature to be monitored to perform overheat protection and a mode control circuit which switches between setting of each of the overcurrent protection circuit and the overheat protection circuit to a normal mode and setting of each of them to a capacitive load driving mode. In in the capacitive load driving mode, the overcurrent protection circuit restricts the output current to an overcurrent protection threshold value or less. Each time the temperature to be monitored rises to a second overheat protection threshold value lower than a first overheat protection threshold value set in the normal mode, the overheat protection circuit repeats forced turning off and restarting of the output switch.

### CROSS REFERENCE TO RELATED APPLICATIONS

This application is a continuation under 35 U.S.C. § 120 of PCT/JP2023/027789, filed Jul. 28, 2023, which is incorporated herein by reference, and which claimed priority to Japanese Application No. 2022-144311, filed Sep. 12, 2022. The present application likewise claims priority under 35 U.S.C. § 119 to Japanese Application No. 2022-144311, filed Sep. 12, 2022, the entire content of which is also incorporated herein by reference.

### TECHNICAL FIELD

The present disclosure relates to a semiconductor device, an electronic device and a vehicle.

### BACKGROUND ART

The applicant of the present application has proposed a large number of new techniques on semiconductor devices such as a vehicle-mounted IPD [intelligent power device] (see, for example, Patent Document 1).

### RELATED ART DOCUMENT

### Patent Document

Patent Document 1: International Publication No. 2017/187785

### BRIEF DESCRIPTION OF DRAWINGS

FIG. 1 is a diagram showing an example of the configuration of an electronic device which includes a semiconductor device;

FIG. 2 is a block circuit diagram showing the electrical structure of the semiconductor device;

FIG. 3 is a diagram showing an example of an electronic device which includes mechanical fuses;

FIG. 4 is a diagram showing an example of a semiconductor device which replaces mechanical fuses;

FIG. 5 is a diagram showing a first example of an abnormality protection operation;

FIG. 6 is a diagram showing a second example of the abnormality protection operation;

FIG. 7 is a diagram showing a third example of the abnormality protection operation;

FIG. 8 is a diagram showing a fourth example of the abnormality protection operation;

FIG. 9 is a diagram showing a first example of a startup operation;

FIG. 10 is a diagram showing a second example of the startup operation;

FIG. 11 is a diagram showing a third example of the startup operation; and

FIG. 12 is an external view showing an example of the configuration of a vehicle.

### DESCRIPTION OF EMBODIMENTS

### <Electronic Device>

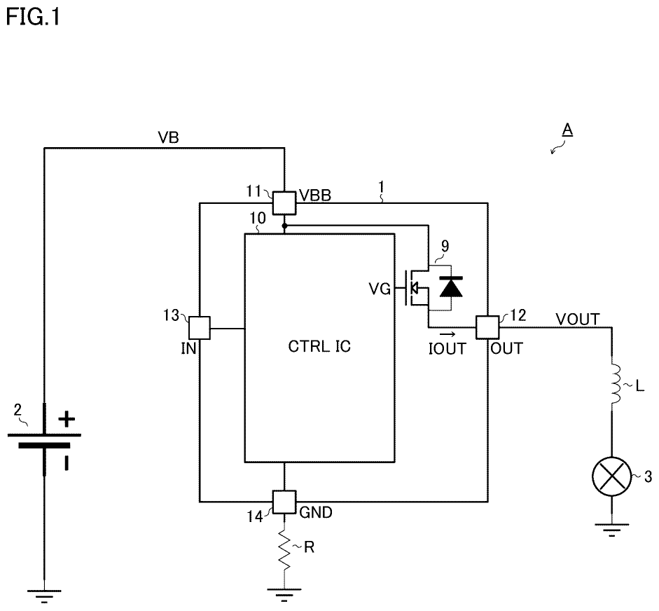

FIG. 1 is a diagram showing an example of the configuration of an electronic device which includes a semiconductor device. The electronic device A of the present configuration example includes a semiconductor device 1, a direct-current power supply 2 and a load 3.

The semiconductor device 1 is a high-side switch IC (a type of IPD) which electrically conducts/interrupts between the direct-current power supply 2 and the load 3, and integrates a power MISFET [metal insulator semiconductor field effect transistor] 9 and a controller 10.

The semiconductor device 1 includes a plurality of external electrodes as a means for establishing electrical connection with the outside of the device. With reference to the figure, the semiconductor device 1 includes a drain electrode 11 (corresponding to a power supply electrode VBB), a source electrode 12 (corresponding to an output electrode OUT), an input electrode 13 (corresponding to an input electrode IN) and a reference voltage electrode 14 (corresponding to a ground electrode GND).

The power MISFET 9 is an example of an insulated gate power transistor (=output switch), and functions as a high-side switch element which electrically conducts/interrupts between the drain electrode 11 and the source electrode 12.

The controller 10 includes a plurality of types of function circuits which realize various functions. Examples of the various types of function circuits include a circuit which generates a gate control signal VG for driving and controlling the power MISFET 9 based on an electrical signal from the outside.

The drain electrode 11 transmits a power supply voltage VB to the drain of the power MISFET 9 and various types of circuits in the controller 10. The source electrode 12 is connected to the source of the power MISFET 9, and transmits an output voltage VOUT and an output current IOUT to the load 3. A signal line (for example, a wire harness) provided between the source electrode 12 and the load 3 generally has an inductance component L (and a resistance component). The input electrode 13 transmits an input voltage (=input signal IN) for driving the controller 10. The reference voltage electrode 14 transmits a reference voltage (for example, a ground voltage) to the controller 10. A resistance component R is generally present between the reference voltage electrode 14 and a ground end.

### <Semiconductor Device>

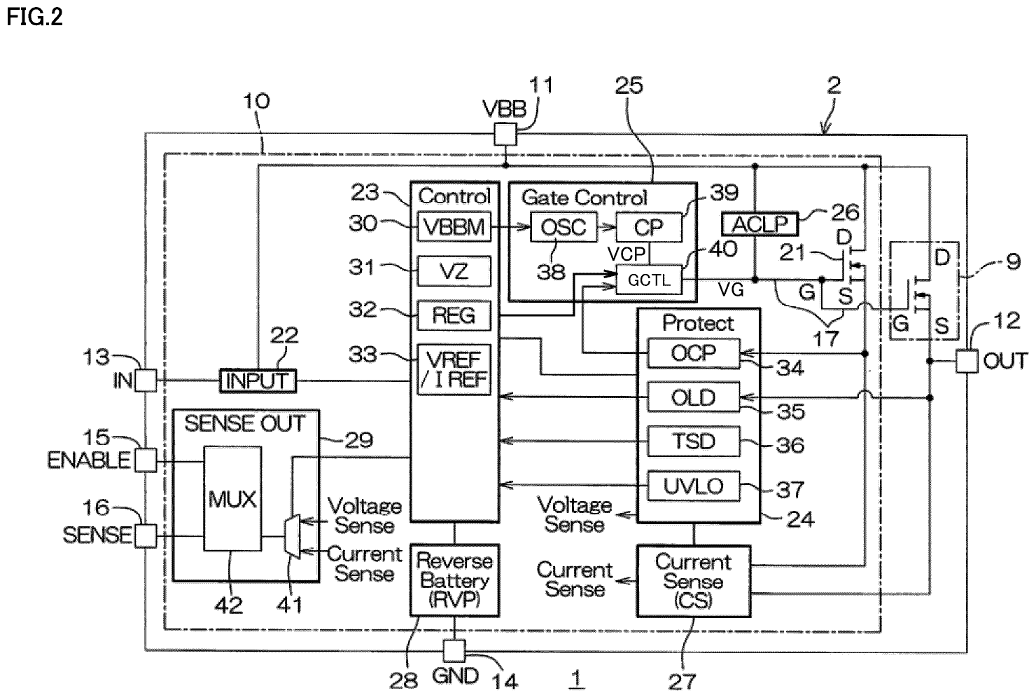

FIG. 2 is a block circuit diagram showing the electrical structure of the semiconductor device 1 shown in FIG. 1. In the following description, a case where the semiconductor device 1 is installed in a vehicle is used as an example. When the semiconductor device 1 is installed in the vehicle, the semiconductor device 1 can be applied as a high-side switch for controlling the energization of a light source such as a bulb lamp or an LED [light emitting diode] lamp or another type of electronic control device.

The semiconductor device 1 includes the drain electrode 11, the source electrode 12, the input electrode 13, the reference voltage electrode 14, an enable electrode 15, a sense electrode 16, a gate control wire 17, the power MISFET 9 and the controller 10.

The drain electrode 11 (=power supply electrode VBB) is connected to the direct-current power supply 2. The drain electrode 11 provides the power supply voltage VB to the power MISFET 9 and the controller 10. The power supply voltage VB may be equal to or greater than 10 V and equal to or less than 20 V. On the other hand, the source electrode 12 (=output electrode OUT) is connected to the load 3.

The input electrode 13 (=input electrode IN) may be connected to a MCU [micro controller unit], a DC/DC converter, an LDO [low drop out] regulator and the like. The input electrode 13 provides an input voltage to the controller 10. The input voltage may be equal to or greater than 1 V and equal to or less than 10 V. The reference voltage electrode 14 is connected to a reference voltage wire (ground end). The reference voltage electrode 14 provides the reference voltage to the power MISFET 9 and the controller 10.

The enable electrode 15 may be connected to the MCU. An electrical signal for enabling or disabling a part or all of functions of the controller 10 is input to the enable electrode 15. The sense electrode 16 transmits an electrical signal for detecting an abnormality of the controller 10 to the outside of the device. The sense electrode 16 may be pulled up or down by a resistor.

The gate of the power MISFET 9 is connected to the controller 10 (in particular, a gate control circuit 25 which will be described later) via the gate control wire 17. The drain of the power MISFET 9 is connected to the drain electrode 11. The source of the power MISFET 9 is connected to the controller 10 (in particular, a current detection circuit 27 which will be described later) and the source electrode 12.

The controller 10 includes a sensor MISFET 21, an input circuit 22, a current/voltage control circuit 23, a protection circuit 24, the gate control circuit 25, an active clamp circuit 26, the current detection circuit 27, a power supply reverse connection protection circuit 28 and an abnormality detection circuit 29.

The gate of the sensor MISFET 21 is connected to the gate control circuit 25. The drain of the sensor MISFET 21 is connected to the drain electrode 11. The source of the sensor MISFET 21 is connected to the current detection circuit 27.

The input circuit 22 is connected to the input electrode 13 and the current/voltage control circuit 23. The input circuit 22 may include a Schmitt trigger circuit. The input circuit 22 shapes the waveform of an electrical signal applied to the input electrode 13. A signal generated by the input circuit 22 is input to the current/voltage control circuit 23.

The current/voltage control circuit 23 is connected to the protection circuit 24, the gate control circuit 25, the power supply reverse connection protection circuit 28 and the abnormality detection circuit 29. The current/voltage control circuit 23 may include a logic circuit.

The current/voltage control circuit 23 generates various voltages according to the electrical signal from the input circuit 22 and an electrical signal from the protection circuit 24. In this form, the current/voltage control circuit 23 includes a drive voltage generation circuit 30, a first constant voltage generation circuit 31, a second constant voltage generation circuit 32 and a reference voltage/reference current generation circuit 33.

The drive voltage generation circuit 30 generates a drive voltage for driving the gate control circuit 25. The drive voltage may be set to a value obtained by subtracting a predetermined value from the power supply voltage VB. The drive voltage generation circuit 30 may generate the drive voltage which is obtained by subtracting 5 V from the power supply voltage VB and is equal to or greater than 5 V and equal to or less than 15 V. The drive voltage is input to the gate control circuit 25.

The first constant voltage generation circuit 31 generates a first constant voltage for driving the protection circuit 24. The first constant voltage generation circuit 31 may include a Zener diode or a regulator circuit (here, the Zener diode). The first constant voltage may be equal to or greater than 1 V and equal to or less than 5 V. The first constant voltage is input to the protection circuit 24 (more specifically, a load open detection circuit 35 which will be described later or the like).

The second constant voltage generation circuit 32 generates a second constant voltage for driving the protection circuit 24. The second constant voltage generation circuit 32 may include a Zener diode or a regulator circuit (here, the regulator circuit). The second constant voltage may be equal to or greater than 1 V and equal to or less than 5 V. The second constant voltage is input to the protection circuit 24 (more specifically, an overheat protection circuit 36 and a low voltage malfunction suppression circuit 37 which will be described later).

The reference voltage/reference current generation circuit 33 generates the reference voltage and a reference current for various types of circuits. The reference voltage may be equal to or greater than 1 V and equal to or less than 5 V. The reference current may equal to or greater than 1 mA and equal to or less than 1 A. The reference voltage and the reference current are input to various types of circuits. When the various types of circuits include a comparator, the reference voltage and the reference current may be input to the comparator.

The protection circuit 24 is connected to the current/voltage control circuit 23, the gate control circuit 25, the abnormality detection circuit 29, the source of the power MISFET 9 and the source of the sensor MISFET 21. The protection circuit 24 includes an overcurrent protection circuit 34, the load open detection circuit 35, the overheat protection circuit 36 and the low voltage malfunction suppression circuit 37.

The overcurrent protection circuit 34 protects the power MISFET 9 from an overcurrent. The overcurrent protection circuit 34 is connected to the gate control circuit 25 and the source of the sensor MISFET 21. The overcurrent protection circuit 34 may include a current monitor circuit. A signal generated by the overcurrent protection circuit 34 is input to the gate control circuit 25 (more specifically, a drive signal output circuit 40 which will be described later).

The load open detection circuit 35 detects the short-circuit state and the open state of the power MISFET 9. The load open detection circuit 35 is connected to the current/voltage control circuit 23 and the source of the power MISFET 9. A signal generated by the load open detection circuit 35 is input to the current/voltage control circuit 23.

The overheat protection circuit 36 monitors the temperature of the power MISFET 9 to protect the power MISFET 9 from an excessive temperature rise. The overheat protection circuit 36 is connected to the current/voltage control circuit 23. The overheat protection circuit 36 may include a temperature-sensitive device such as a temperature-sensitive diode or a thermistor. A signal generated by the overheat protection circuit 36 is input to the current/voltage control circuit 23.

When the power supply voltage VB is less than a predetermined value, the low voltage malfunction suppression circuit 37 suppresses the malfunction of the power MISFET 9. The low voltage malfunction suppression circuit 37 is connected to the current/voltage control circuit 23. A signal generated by the low voltage malfunction suppression circuit 37 is input to the current/voltage control circuit 23.

The gate control circuit 25 controls the on-state and the off-state of the power MISFET 9 and the on-state and the off-state of the sensor MISFET 21. The gate control circuit 25 is connected to the current/voltage control circuit 23, the protection circuit 24, the gate of the power MISFET 9 and the gate of the sensor MISFET 21.

The gate control circuit 25 outputs the gate control signal VG to the gate control wire 17 according to an electrical signal from the current/voltage control circuit 23 and the electrical signal from the protection circuit 24. The gate control signal VG is input via the gate control wire 17 to the gate of the power MISFET 9 and the gate of the sensor MISFET 21. More specifically, the gate control circuit 25 controls the gate control signal VG according to the electrical signal (input signal) applied to the input electrode 13 to turn on and off the power MISFET 9.

More specifically, the gate control circuit 25 includes an oscillator circuit 38, a charge pump circuit 39 and the drive signal output circuit 40. The oscillator circuit 38 oscillates in response to an electric signal from the current/voltage control circuit 23 to generate a predetermined electrical signal. The electrical signal generated by the oscillator circuit 38 is input to the charge pump circuit 39. The charge pump circuit 39 generates a step-up voltage VCP based on the electrical signal from the oscillator circuit 38. The step-up voltage VCP generated by the charge pump circuit 39 is input to the drive signal output circuit 40.

The drive signal output circuit 40 is operated by receiving the step-up voltage VCP output from the charge pump circuit 39, and generates the gate control signal VG according to the electrical signal from the protection circuit 24 (more specifically, the overcurrent protection circuit 34). The gate control signal VG is input via the gate control wire 17 to the gate of the power MISFET 9 and the gate of the sensor MISFET 21. The sensor MISFET 21 and the power MISFET 9 are controlled simultaneously by the gate control circuit 25.

The active clamp circuit 26 protects the power MISFET 9 from a back electromotive force. The active clamp circuit 26 is connected to the drain electrode 11, the gate of the power MISFET 9 and the gate of the sensor MISFET 21. The active clamp circuit 26 may include a plurality of diodes.

The active clamp circuit 26 may include a plurality of diodes connected in forward bias. The active clamp circuit 26 may include a plurality of diodes connected in reverse bias. The active clamp circuit 26 may include a plurality of diodes connected in forward bias and a plurality of diodes connected in reverse bias.

The plurality of diodes may include a pn junction diode or a Zener diode, or a pn junction diode and a Zener diode. The active clamp circuit 26 may include a plurality of Zener diodes connected in forward bias. The active clamp circuit 26 may include a Zener diode and a pn junction diode connected in reverse bias.

The current detection circuit 27 detects a current flowing through the power MISFET 9 and the sensor MISFET 21. The current detection circuit 27 is connected to the protection circuit 24, the abnormality detection circuit 29, the source of the power MISFET 9 and the source of the sensor MISFET 21. The current detection circuit 27 generates a current detection signal according to an electrical signal (=output current IOUT) generated by the power MISFET 9 and an electrical signal (=sense current ISNS indicating the same behavior as the output current IOUT) generated by the sensor MISFET 21. The current detection signal is input to the abnormality detection circuit 29.

When the direct-current power supply 2 is reversely connected, the power supply reverse connection protection circuit 28 protects the current/voltage control circuit 23, the power MISFET 9 and the like from a reverse voltage. The power supply reverse connection protection circuit 28 is connected to the reference voltage electrode 14 and the current/voltage control circuit 23.

The abnormality detection circuit 29 monitors the voltage of the protection circuit 24. The abnormality detection circuit 29 is connected to the current/voltage control circuit 23, the protection circuit 24 and the current detection circuit 27. When an abnormality (such as a variation in voltage) occurs in any one of the overcurrent protection circuit 34, the load open detection circuit 35, the overheat protection circuit 36 and the low voltage malfunction suppression circuit 37, the abnormality detection circuit 29 generates an abnormality detection signal corresponding to the voltage of the protection circuit 24, and outputs it to the outside.

More specifically, the abnormality detection circuit 29 includes a first multiplexer circuit 41 and a second multiplexer circuit 42. The first multiplexer circuit 41 includes two input portions, one output portion and one selective control input portion. The protection circuit 24 and the current detection circuit 27 are connected to the input portions of the first multiplexer circuit 41. The second multiplexer circuit 42 is connected to the output portion of the first multiplexer circuit 41. The current/voltage control circuit 23 is connected to the selective control input portion of the first multiplexer circuit 41.

The first multiplexer circuit 41 generates the abnormality detection signal according to the electrical signal from the current/voltage control circuit 23, a voltage detection signal from the protection circuit 24 and a current detection signal from the current detection circuit 27. The abnormality detection signal generated by the first multiplexer circuit 41 is input to the second multiplexer circuit 42.

The second multiplexer circuit 42 includes two input portions and one output portion. The output portion of the second multiplexer circuit 42 and the enable electrode 15 are connected to the input portions of the second multiplexer circuit 42. The sense electrode 16 is connected to the output portion of the second multiplexer circuit 42.

When the MCU is connected to the enable electrode 15, and the pull-up or pull-down resistor is connected to the sense electrode 16, an on-signal is input to the enable electrode 15 from the MCU, and the abnormality detection signal is taken out from the sense electrode 16. The abnormality detection signal is converted into an electrical signal by the resistor connected to the sense electrode 16. An abnormality in the state of the semiconductor device 1 is detected based on this electrical signal.

### <Problems in Mechanical Fuses>

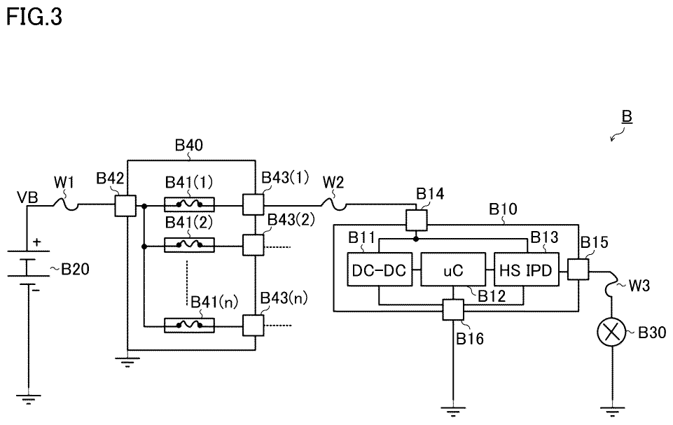

FIG. 3 is a diagram showing an example of an electronic device which includes mechanical fuses. The electronic device B of the present configuration example includes a control unit B10, a battery B20, a load B30 and a fuse box B40.

The control unit B10 receives the supply of the power supply voltage VB from the battery B20 via the fuse box B40 to drive the load B30. With reference to the figure, the control unit B10 includes a DC/DC converter B11, a microcomputer B12, an upper switch B13, a power supply electrode B14, an output electrode B15 and a reference voltage electrode B16. The control unit B10 may be, for example, an ECU [electronic control unit].

The DC/DC converter B11 generates a desired internal power supply voltage from the power supply voltage VB, and outputs the internal power supply voltage to the portions (such as the microcomputer B12) of the control unit B10.

The microcomputer B12 receives the supply of the internal power supply voltage from the DC/DC converter B11 to perform on/off control on the upper switch B13.

The upper switch B13 is connected between the power supply electrode B14 and the output electrode B15 and is subjected to the on/off control corresponding to an instruction from the microcomputer B12.

The power supply electrode B14 receives the supply of the power supply voltage VB from the battery B20 via the fuse box B40. For example, the output electrode B15 is connected to the load B30 via a wire W3. For example, the reference voltage electrode B16 is connected to the ground end.

The fuse box B40 includes n fuses B41(1) to B41 (n), an input electrode B42 and output electrodes B43(1) to B43 (n).

The fuse B41 (i) (where i=1, 2, . . . and n) is connected between the input electrode B42 and the output electrode B43 (i). The fuse B41 (i) is a so-called mechanical fuse and is blown due to Joule heat when a current exceeding its rated current flows through the fuse B41 (i), with the result that the circuit is protected.

For example, the input electrode B42 is connected to the positive end (=the application end of the power supply voltage VB) of the battery B20 via a wire W1. For example, the output electrode B43(1) is connected to the power supply electrode B14 of the control unit B10 via a wire W2.

In the electronic device B using the fuse box B40, there are two problems. The first problem is that the reaction time (=the time required for the blowing) of the fuse B41 (i) is unclear and is not accurate. Hence, damage to the control unit B10 to be protected can often be a problem. The second problem is that it is necessary to replace the fuse B41 (i) which has been blown. In most cases, a complete system replacement (=replacement of the fuse box B40) is required.

In order to solve the problem described above, for example, it is conceivable to use an electronic fuse (so-called e-fuse) utilizing an IPD instead of the mechanical fuse. However, the control unit B10 often includes its own input capacitor in a subsystem such as the DC/DC converter B11. Hence, the control unit B10 functions as a capacitive load having a large capacitance value (generally in a mF range) from the viewpoint of the electronic fuse.

Therefore, in a typical electronic fuse using an IPD, the size of an output switch needs to be increased so that an overheat protection function is not activated even if a large inrush current flows when the control unit B10 is started up. This increases the cost of the IPD.

If a pre-charge circuit using discrete components is prepared, it is possible to avoid increasing the size of the output switch of the IPD. However, it is necessary to increase the number of components and the size of a PCB [printed circuit board], with the result that this may result in an increase in the cost of the entire electronic device.

In the following description, a novel semiconductor device which can solve the above problems will be proposed.

### <Replacement of Mechanical Fuses>

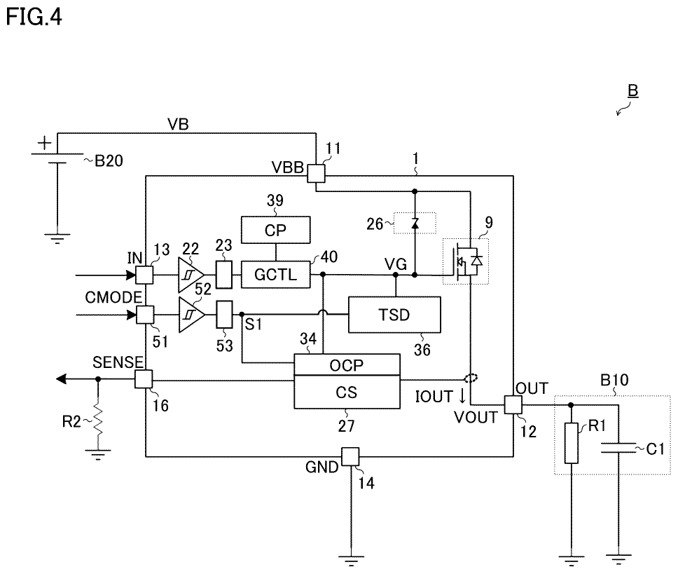

FIG. 4 is a diagram showing an example of a semiconductor device which replaces the mechanical fuses. In the electronic device B of the present configuration example, the fuse box B40 is replaced by the semiconductor device 1 based on FIG. 3 described above.

The control unit B10 which is externally attached to the source electrode 12 (=output electrode OUT) of the semiconductor device 1 functions as a capacitive load having a large capacitance value from the viewpoint of the semiconductor device 1. Hence, the control unit B10 is equivalently shown as the parallel circuit of a capacitor C1 and a resistor R1. In the figure, a resistor R2 for pulling down the sense electrode 16 to the ground end is explicitly shown.

The semiconductor device 1 basically has the same configuration as in FIG. 2 described previously, and further includes a CMODE enable electrode 51, an input circuit 52 and a mode control circuit 53. Hence, the constituent elements which have already been described are identified with the same symbols as in FIG. 2, thus repeated description is omitted and further constituent elements and constituent elements related thereto will be mainly described.

The power MISFET 9 is an output switch which electrically conducts/interrupts between the drain electrode 11 and the source electrode 12 according to the gate control signal VG.

The overcurrent protection circuit 34 detects the output current IOUT flowing through the power MISFET 9 and controls the gate control signal VG to perform overcurrent protection.

The overheat protection circuit 36 detects a temperature to be monitored and controls the gate control signal VG to perform overheat protection.

The temperature to be monitored may be a first temperature Temp1 which is detected in a power element formation region including the power MISFET 9. The first temperature Temp1 may be, for example, the pn junction temperature Tj1 of the power element formation region.

The temperature to be monitored may be a temperature difference ΔTemp (=Temp 1−Temp2) between the first temperature Temp1 and a second temperature Temp2 detected in a region other than the power element formation region. The second temperature Temp2 may be, for example, the pn junction temperature Tj2 of an analogue circuit formation region or a logic circuit formation region, the case temperature Tc of the semiconductor device 1 or the ambient temperature Ta around the semiconductor device 1.

The CMODE enable electrode 51 is an external electrode for switching between enabling and disabling of the mode control circuit 53.

The input circuit 52 shapes the waveform of an electrical signal applied to the CMODE enable electrode 51, and outputs the electrical signal to the mode control circuit 53.

The mode control circuit 53 generates a mode control signal S1 for switching between setting of each of the overcurrent protection circuit 34 and the overheat protection circuit 36 to a normal mode and setting of each of the overcurrent protection circuit 34 and the overheat protection circuit 36 to a capacitive load driving mode. The mode control signal S1 is output to each of the overcurrent protection circuit 34 and the overheat protection circuit 36.

For example, the mode control circuit 53 is enabled when the electrical signal applied to the CMODE enable electrode 51 is high to enter a state where the logic level of the mode control signal S1 can be switched. For example, the overcurrent protection circuit 34 and the overheat protection circuit 36 are set to the normal mode when the mode control signal S1 is high and are set to the capacitive load driving mode when the mode control signal S1 is low.

In the capacitive load driving mode, the overcurrent protection circuit 34 performs a current restriction operation of restricting the output current IOUT to an overcurrent protection threshold value Iocp or less. In particular, in the capacitive load driving mode, the overcurrent protection threshold value Iocp is set to a second overcurrent protection threshold value I2 (for example, I2=I1×0.7) lower than a first overcurrent protection threshold value I1 set in the normal mode.

Each time the temperature to be monitored (for example, the temperature difference ΔTemp described previously) rises to an overheat protection threshold value Ttsd, the overheat protection circuit 36 repeats the forced turning off and the restarting of the power MISFET 9. In particular, in the capacitive load driving mode, the overheat protection threshold value Ttsd is set to a second overheat protection threshold value T2 (for example, T2=30° C.) lower than a first overheat protection threshold value T1 (or example, T1=90° C.) set in the normal mode.

On the other hand, for example, the mode control circuit 53 is disabled when the electrical signal applied to the CMODE enable electrode 51 is low. In this case, the mode control signal S1 is fixed to a high level. Hence, the overcurrent protection circuit 34 and the overheat protection circuit 36 are set to the normal mode.

As described above, in the electronic device B of the present configuration example, the fuse box B40 described previously is replaced by the semiconductor device 1. In other words, when the output current IOUT is excessively increased (for example, several tens of amperes to 100 A), the power MISFET 9 is forcedly turned off, and thus the output current IOUT is restricted or interrupted with high speed and high accuracy. Hence, both the semiconductor device 1 and the control unit B10 can be safely protected. Unlike the configuration using mechanical fuses, even if a failure occurs, there is no need to replace the blown fuse B41 (i).

Furthermore, the semiconductor device 1 includes the capacitive load driving mode as its operation mode. Hence, it is possible to appropriately drive a capacitive load (in the figure, the control unit B10) without the need of an increase in the size of the power MISFET 9 or an additional external component.

Differences between the normal mode and the capacitive load driving mode of the semiconductor device 1 will be described below while attention is being focused on the abnormality protection operation of the semiconductor device 1. The advantages of use of the capacitive load driving mode will be clarified by this description.

### <Abnormality Protection Operation>

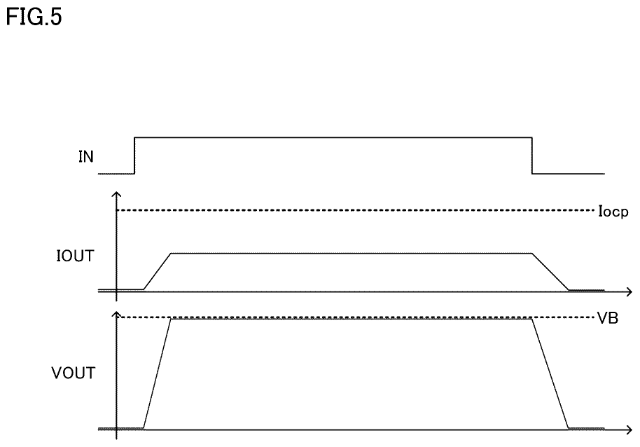

FIG. 5 is a diagram showing a first example of the abnormality protection operation performed by the semiconductor device 1 shown in FIG. 4. The figure shows a voltage applied to the input electrode IN(=input voltage), the output current IOUT and the output voltage VOUT sequentially from above.

The figure shows a behavior when the resistive load (or an inductive load) is driven by the semiconductor device 1 shown in FIG. 4. In this case, when an electrical signal applied to the input electrode IN is raised to a high level, the output voltage VOUT rises to the power supply voltage VB. The output current IOUT reaches a target value (nominal value) without exceeding the overcurrent protection threshold value Iocp.

The behavior described above is exhibited regardless of whether the overcurrent protection circuit 34 and the overheat protection circuit 36 are set to the normal mode or to the capacitive load driving mode. In other words, when the resistive load or the inductive load is driven by the semiconductor device 1 shown in FIG. 4, even if the overcurrent protection circuit 34 and the overheat protection circuit 36 are set to the capacitive load driving mode, there is no particular effect on the operation of the semiconductor device 1.

On the other hand, when the capacitive load is driven by the semiconductor device 1 shown in FIG. 4, the behavior of the semiconductor device 1 differs according to whether the overcurrent protection circuit 34 and the overheat protection circuit 36 are set to the normal mode or to the capacitive load driving mode.

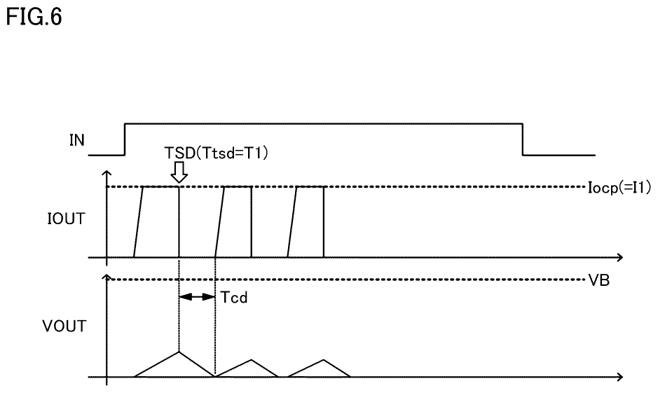

FIG. 6 is a diagram showing a second example of the abnormality protection operation performed by the semiconductor device 1 shown in FIG. 4. The figure shows the voltage applied to the input electrode IN(=input voltage), the output current IOUT and the output voltage VOUT sequentially from above.

The figure shows a behavior when the capacitive load (for example, the control unit B10) is driven by the semiconductor device 1 shown in FIG. 4. It is assumed that in the figure, the electrical signal applied to the CMODE enable electrode 51 is set low, and the mode control signal S1 is fixed to a high level. In other words, the figure shows the behavior when the overcurrent protection circuit 34 and the overheat protection circuit 36 are set to the normal mode.

In this case, when the electrical signal applied to the input electrode IN is raised to a high level, a large inrush current flows through the capacitive load, and thus the output current IOUT is increased sharply. Here, the overcurrent protection circuit 34 performs the current restriction operation such that the output current IOUT is equal to or less than the overcurrent protection threshold value Iocp (=I1).

When the capacitance value of the capacitive load is large, and the size of the power MISFET 9 is small, heat generated by the power MISFET 9 is increased. Consequently, the overheat protection circuit 36 repeats the forced turning off and the restarting of the power MISFET 9 each time the temperature to be monitored (for example, the temperature difference ΔTemp described previously) rises to the overheat protection threshold value Ttsd (=T1).

A certain amount of cooling time Ted is needed before the power MISFET 9 is restarted after being forcedly turned off by an overheat protection operation. During that time, a state where the output current IOUT is not supplied to the capacitive load is continued. Hence, as shown in the figure, this may cause a failure with the rise of the output voltage VOUT.

When the size of the power MISFET 9 is increased, the overheat protection operation is unlikely to be performed, and thus the output voltage VOUT can be correctly raised. However, as described previously, an increase in the size of the power MISFET 9 leads to an increase in the cost of the semiconductor device 1.

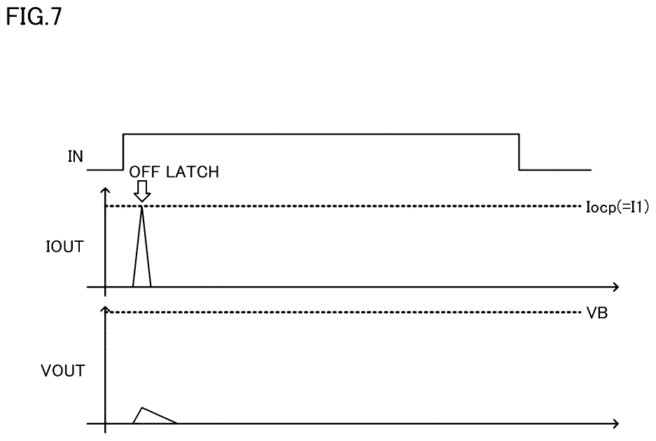

FIG. 7 is a diagram showing a third example of the abnormality protection operation performed by the semiconductor device 1 shown in FIG. 4. The figure shows the voltage applied to the input electrode IN(=input voltage), the output current IOUT and the output voltage VOUT sequentially from above.

As with FIG. 6 described above, the figure shows a behavior when the capacitive load (for example, the control unit B10) is driven by the semiconductor device 1 shown in FIG. 4. The figure is the same as FIG. 6 described above in that the overcurrent protection circuit 34 and the overheat protection circuit 36 are set to the normal mode. However, an overcurrent protection operation in the normal mode is different from that in FIG. 6 described above.

With reference to the figure, when the output current IOUT is increased to the overcurrent protection threshold value Iocp (=11), the overcurrent protection circuit 34 performs an off-latch operation to continue to forcedly turn off the power MISFET 9.

The off-latch operation as described above is extremely effective for the purpose of complying with strict safety standards such as AEC-Q100-012 standard. However, in view of driving of the capacitive load, the off-latch operation is unsuitable. This is because when the power MISFET 9 is forcedly latched off, the supply of the output current IOUT to the capacitive load is completely interrupted, and thus the output voltage VOUT is not raised at all.

Hence, when the overcurrent protection circuit 34 performs the off-latch operation, there is no point in an increase in the size of the power MISFET 9, and an external pre-charge circuit is essential.

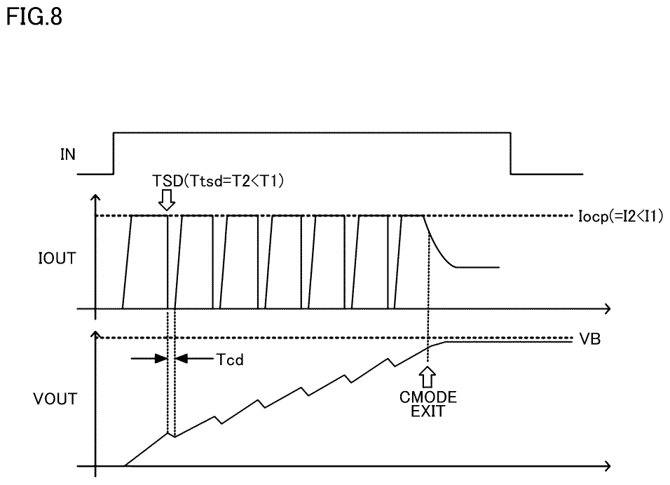

FIG. 8 is a diagram showing a fourth example of the abnormality protection operation performed by the semiconductor device 1 shown in FIG. 4. The figure shows the voltage applied to the input electrode IN(=input voltage), the output current IOUT and the output voltage VOUT sequentially from above.

As with FIGS. 6 and 7 described previously, the figure shows a behavior when the capacitive load (for example, the control unit B10) is driven by the semiconductor device 1 shown in FIG. 4. However, the figure is different from FIGS. 6 and 7 described previously in that the overcurrent protection circuit 34 and the overheat protection circuit 36 are set not to the normal mode but to the capacitive load driving mode.

With reference to the figure, in the capacitive load driving mode, the overcurrent protection circuit 34 performs the current restriction operation of restricting the output current IOUT to the overcurrent protection threshold value Iocp or less (=I2<I1). Each time the temperature to be monitored (for example, the temperature difference ΔTemp described previously) rises to the overheat protection threshold value Ttsd (=T2<T1), the overheat protection circuit 36 repeats the forced turning off and the restarting of the power MISFET 9.

As described above, in the capacitive load driving mode, in a state where both the overcurrent protection threshold value Iocp and the overheat protection threshold value Ttsd (at least the overheat protection threshold value Ttsd) are lowered below the normal mode, the overheat protection circuit 36 repeats the forced turning off and the restarting of the power MISFET 9.

Hence, the cooling time Ted until the power MISFET 9 is restarted after being forcedly turned off by the overheat protection operation is reduced. Consequently, it is possible to raise the output voltage VOUT by charging the capacitive load without increasing the size of the power MISFET 9 or using an external pre-charge circuit.

As described above, in the capacitive load driving mode, it is possible to appropriately drive the capacitive load which is difficult to drive in the normal mode.

As described previously, in the capacitive load driving mode, the overcurrent protection threshold value Iocp and the overheat protection threshold value Ttsd are lowered below the normal mode. Hence, while the capacitive load is being charged, the semiconductor device 1 and the capacitive load (for example, the control unit B10) connected thereto are maintained in a safety operation region (so-called SOA [safety operation area]).

In the capacitive load driving mode, at least one of the second overcurrent protection threshold value I2 and the second overheat protection threshold value T2 may be stepwise increased to the first overcurrent protection threshold value I1 and the first overheat protection threshold value T1 according to an increase in the output voltage VOUT or over time.

When a predetermined return condition (details of which will be described later) is satisfied, the mode control circuit 53 may switch the overcurrent protection circuit 34 and the overheat protection circuit 36 from the capacitive load driving mode to the normal mode (see “CMODE EXIT” in the figure).

For example, as in the capacitive load driving mode, the overcurrent protection operation after return to the normal mode may be the current restriction operation of restricting the output current IOUT to the overcurrent protection threshold value Iocp (=11) or less.

For example, the overcurrent protection operation after return to the normal mode may be a hiccup operation of repeating the forced turning off and the restarting of the power MISFET 9 each time the output current IOUT is increased to the overcurrent protection threshold value Iocp (=11). By the hiccup operation as described above, heat generated by the power MISFET 9 is suppressed as compared with the overcurrent protection operation described above.

For example, the overcurrent protection operation after return to the normal mode may be the off-latch operation of continuing the forced turning off of the power MISFET 9 when the output current IOUT is increased to the overcurrent protection threshold value (=11). By the off-latch operation as described above, it is possible to further enhance safety when an overcurrent is generated as compared with the current restriction operation and the hiccup operation described above.

As described above, in the semiconductor device 1 of the present configuration example, as necessary, the normal mode and the capacitive load driving mode are switched. Hence, for example, the semiconductor device 1 is compatible with process technologies in which the on-resistance of the power MISFET 9 is relatively high, and which require a stricter overcurrent protection operation.

When the operation and the architecture of the capacitive load driving mode described above are summarized, the most important attributes are as follows.
(1) In the capacitive load driving mode, as the overheat protection operation, an overheat detection/restart operation (=a state where the forced turning off of the power MISFET 9 performed by detection of overheat and the restarting of the power MISFET 9 performed by release of overheat are repeated) is forced. In this way, the capacitive load is repeatedly charged until the output voltage VOUT is sufficiently raised.
(2) In the capacitive load driving mode, as the overcurrent protection operation, the current restriction operation is forced. In this way, it is possible to prevent the output current IOUT from being off-latched before the capacitive load is completely charged.
(3) In the capacitive load driving mode, the overcurrent protection threshold value Iocp is lowered (I1→I2). In this way, the peak of an inrush current which flows through the capacitive load being charged is reduced. For example, the second overcurrent protection threshold value I2 set in the capacitive load driving mode may be 70% (that is, I2=I1×0.7) of the first overcurrent protection threshold value I1 set in the normal mode. However, there is no limitation on the ratio described above.
(4) In the capacitive load driving mode, the overheat protection threshold value Ttsd is lowered (T1->T2). This has two effects. The first effect is that while the capacitive load is not being fully charged, that is, while the capacitive load is acting as a virtual short circuit, the semiconductor device 1 is maintained in the safety operation region. The second effect is that since the semiconductor device 1 is rapidly cooled to an overheat release temperature (safety temperature), the timing of restarting of the power MISFET 9 is accelerated, and thus the capacitive load can be continuously charged. In other words, a charge pump effect is obtained, and thus it is possible to reliably raise the output voltage VOUT.
(5) When the output voltage VOUT exceeds a predetermined threshold voltage Vth, the mode is automatically returned from the capacitive load driving mode to the normal mode. In other words, the threshold voltage Vth corresponds to a threshold value for completion of the capacitive load driving mode. As described previously, the overcurrent protection operation after return to the normal mode may be any one of the current restriction operations, the hiccup operation and the off-latch operation.
(6) When a predetermined time (for example, 50 ms) elapses after the capacitive load driving mode is set, the mode may be automatically returned to the normal mode. In this way, even if an output short circuit or another failure occurs, the semiconductor device 1 can be maintained in the safety operation region.
(7) The semiconductor device 1 includes the CMODE enable electrode 51 for switching between enabling and disabling of the mode control circuit 53 (hence, the capacitive load driving mode). In this way, a user can arbitrarily determine whether the capacitive load driving mode is utilized. Furthermore, it is possible to easily switch between enabling and disabling of the mode control circuit 53 without applying a special gimmick (such as high-frequency PWM [pulse width modulation] drive or multi-level input) to the input electrode IN.

### <Startup Operation>

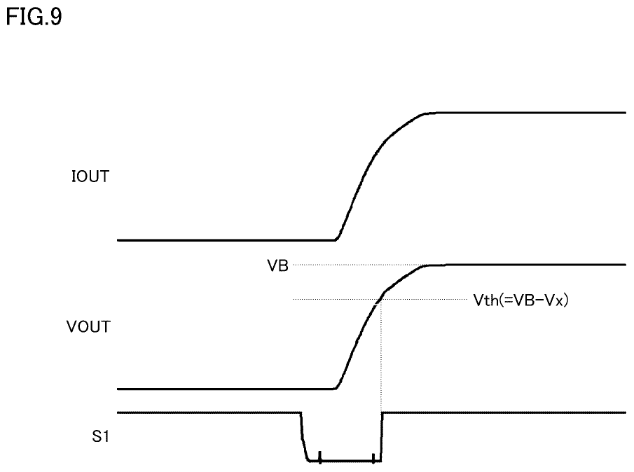

FIG. 9 is a diagram showing a first example of a startup operation performed by the semiconductor device 1 shown in FIG. 4. The figure shows the output current IOUT, the output voltage VOUT and the mode control signal S1 sequentially from above.

The figure shows a behavior when the pure resistive load (for example, R1=2Ω, C1=0 F) is driven by the semiconductor device 1 shown in FIG. 4. The on-resistance of the power MISFET 9 is assumed to be 4 mΩ.

As shown in the figure, the mode control circuit 53 drops the mode control signal S1 to a low level when the power MISFET 9 is turned on. Hence, the overcurrent protection circuit 34 and the overheat protection circuit 36 are set to the capacitive load driving mode described previously. The capacitive load driving mode does not affect the driving operation (for example, a slew rate) of the resistive load at all.

When a predetermined return condition is satisfied, the mode control circuit 53 raises the mode control signal S1 to a high level. In this way, the overcurrent protection circuit 34 and the overheat protection circuit 36 are switched from the capacitive load driving mode to the normal mode.

With reference to the figure, it is detected as the return condition that the output voltage VOUT exceeds the predetermined threshold voltage Vth. For example, the threshold voltage Vth may be set to a voltage value (Vth=VB−Vx) which is lower than the power supply voltage VB (for example, 14 V) by a bias voltage Vx (for example, 2 V). By the setting as described above, when the output voltage VOUT is sufficiently raised, the capacitive load driving mode is automatically completed.

It may be detected as the return condition that a predetermined time (for example, 50 ms) elapses after the mode control signal S1 is dropped to a low level.

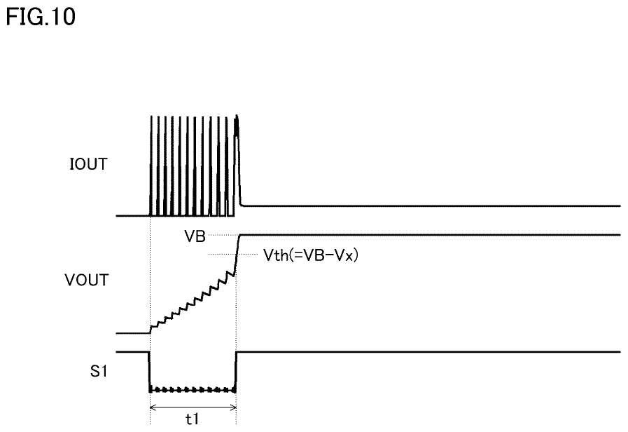

FIG. 10 is a diagram showing a second example of the startup operation performed by the semiconductor device 1 shown in FIG. 4. As with FIG. 9 described above, the figure shows the output current IOUT, the output voltage VOUT and the mode control signal S1 sequentially from above.

The figure shows a behavior when the capacitive load (for example, R1=2Ω, C1=1 mF) is driven by the semiconductor device 1 shown in FIG. 4. The on-resistance of the power MISFET 9 is assumed to be 4 mΩ.

As shown in the figure, the mode control signal S1 is dropped to a low level when the power MISFET 9 is turned on, and thus the overcurrent protection circuit 34 and the overheat protection circuit 36 are set to the capacitive load driving mode. In this way, the output voltage VOUT rises to the threshold voltage Vth during a startup time t1 (for example, less than 2 ms) within a required range. The return condition (output voltage monitoring or timer monitoring) from the capacitive load driving mode to the normal mode is the same as that described previously.

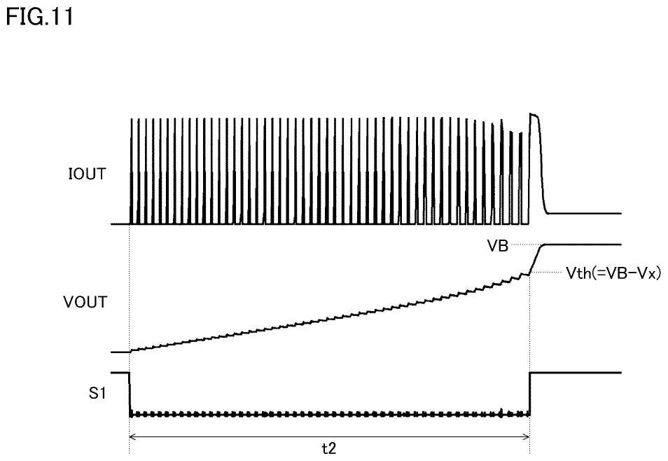

FIG. 11 is a diagram showing a third example of the startup operation performed by the semiconductor device 1 shown in FIG. 4. As with FIGS. 9 and 10 described previously, the figure shows the output current IOUT, the output voltage VOUT and the mode control signal S1 sequentially from above.

The figure shows a behavior when a larger capacitive load (for example, R1=2Ω, C1=4 mF) than in FIG. 10 is driven by the semiconductor device 1 shown in FIG. 4. The on-resistance of the power MISFET 9 is assumed to be 4 mΩ.

As shown in the figure, the mode control signal S1 is dropped to a low level when the power MISFET 9 is turned on, and thus the overcurrent protection circuit 34 and the overheat protection circuit 36 are set to the capacitive load driving mode. In this way, the output voltage VOUT rises to the threshold voltage Vth during a startup time t2 (for example, less than 7.5 ms) within the required range. The return condition (output voltage monitoring or timer monitoring) from the capacitive load driving mode to the normal mode is the same as that described previously.

### <Application to Vehicle>

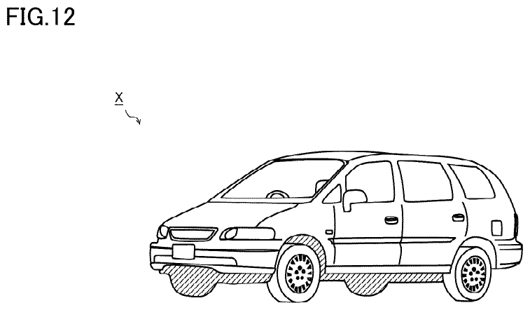

FIG. 12 is an external view showing an example of the configuration of a vehicle. The vehicle X of the present configuration example installs various electronic devices which are operated by receiving the supply of power from a battery.

Examples of the vehicle X include an engine vehicle and electric vehicles (xEVs such as a BEV [battery electric vehicle], an HEV [hybrid electric vehicle], a PHEV/PHV [plug-in hybrid electric vehicle/plug-in hybrid vehicle] and an FCEV/FCV [fuel cell electric vehicle/fuel cell vehicle]).

The semiconductor device 1 described above can be incorporated in any one of the electronic devices installed in the vehicle X.

### SUMMARY

According to the present disclosure, it is possible to provide a semiconductor device, an electronic device, and a vehicle that are capable of appropriately driving a capacitive load without disturbing an abnormality protection function. The various embodiments described above will be generally described below.

For example, a semiconductor device disclosed in the present specification includes: an output switch; an overcurrent protection circuit configured to detect an output current flowing through the output switch to perform overcurrent protection; an overheat protection circuit configured to detect a temperature to be monitored to perform overheat protection; and a mode control circuit configured to switch between setting of each of the overcurrent protection circuit and the overheat protection circuit to a normal mode and setting of each of the overcurrent protection circuit and the overheat protection circuit to a capacitive load driving mode. In the capacitive load driving mode, the overcurrent protection circuit restricts the output current to an overcurrent protection threshold value or less, and each time the temperature to be monitored rises to a second overheat protection threshold value lower than a first overheat protection threshold value set in the normal mode, the overheat protection circuit repeats forced turning off and restarting of the output switch (first configuration).

In the semiconductor device of the first configuration, in the capacitive load driving mode, the second overheat protection threshold value may be increased stepwise to the first overheat protection threshold value (second configuration).

In the semiconductor device of the first or second configuration, in the capacitive load driving mode, the overcurrent protection threshold value may be set to a second overcurrent protection threshold value lower than a first overcurrent protection threshold value set in the normal mode (third configuration).

In the semiconductor device of the third configuration, in the capacitive load driving mode, a second overcurrent protection threshold value may be increased stepwise to a first overcurrent protection threshold value (fourth configuration).

The semiconductor device of any one of the first to fourth configurations may further include: an enable electrode configured to switch between enabling and disabling of the mode control circuit (fifth configuration).

In the semiconductor device of any one of the first to fifth configurations, the mode control circuit may set the overcurrent protection circuit and the overheat protection circuit to the capacitive load driving mode when the output switch is turned on (sixth configuration).

In the semiconductor device of any one of the first to sixth configurations, when a return condition is satisfied, the mode control circuit may switch the overcurrent protection circuit and the overheat protection circuit from the capacitive load driving mode to the normal mode (seventh configuration).

In the semiconductor device of any one of the first to seventh configurations, in the normal mode, the overcurrent protection circuit may perform one of: a current restriction operation of restricting the output current to the overcurrent protection threshold value or less; a hiccup operation of repeating the forced turning off and the restarting of the output switch each time the output current is increased to the overcurrent protection threshold value; and an off-latch operation of continuing the forced turning off of the output switch when the output current is increased to the overcurrent protection threshold value (eighth configuration).

In the semiconductor device of any one of the first to eighth configurations, the temperature to be monitored may be a first temperature that is detected in a power element region including the output switch or a temperature difference between the first temperature and a second temperature that is detected in a region other than the power element region (ninth configuration).

For example, an electronic device disclosed in the present specification includes: the semiconductor device of any one of the first to ninth configurations; and a load configured to receive supply of the output current from the semiconductor device (tenth configuration).

For example, a vehicle disclosed in the present specification includes: : the electronic device of the tenth configuration (eleventh configuration).

### <Other Variations>

In addition to the embodiments described above, the various technical features disclosed in the present specification can be modified in various manners without departing from the spirit of the technical creation thereof.

For example, although in the embodiments described above, the high-side switch IC which replaces mechanical fuses is illustrated, a target on which the capacitive load driving mode is implemented is not limited to the high-side switch IC. In other words, the capacitive load driving mode can also be widely implemented on other IPDs (such as a low-side switch IC).

As described above, the embodiments described above should be considered to be illustrative in all respects and not restrictive. The technical range of the present disclosure should be considered to be specified by the scope of claims, and to include meanings equivalent to the scope of claims and all changes within the range.

1. A semiconductor device comprising:
an output switch;
an overcurrent protection circuit configured to detect an output current flowing through the output switch to perform overcurrent protection;
an overheat protection circuit configured to detect a temperature to be monitored to perform overheat protection; and
a mode control circuit configured to switch between setting of each of the overcurrent protection circuit and the overheat protection circuit to a normal mode and setting of each of the overcurrent protection circuit and the overheat protection circuit to a capacitive load driving mode,
wherein in the capacitive load driving mode,
the overcurrent protection circuit restricts the output current to an overcurrent protection threshold value or less, and
each time the temperature to be monitored rises to a second overheat protection threshold value lower than a first overheat protection threshold value set in the normal mode, the overheat protection circuit repeats forced turning off and restarting of the output switch.

2. The semiconductor device according to claim 1,
wherein in the capacitive load driving mode, the second overheat protection threshold value is increased stepwise to the first overheat protection threshold value.

3. The semiconductor device according to claim 1,
wherein in the capacitive load driving mode, the overcurrent protection threshold value is set to a second overcurrent protection threshold value lower than a first overcurrent protection threshold value set in the normal mode.

4. The semiconductor device according to claim 2,
wherein in the capacitive load driving mode, a second overcurrent protection threshold value is increased stepwise to a first overcurrent protection threshold value.

5. The semiconductor device according to claim 1, further comprising:
an enable electrode configured to switch between enabling and disabling of the mode control circuit.

6. The semiconductor device according to claim 1,
wherein the mode control circuit sets the overcurrent protection circuit and the overheat protection circuit to the capacitive load driving mode when the output switch is turned on.

7. The semiconductor device according to claim 1,
wherein when a return condition is satisfied, the mode control circuit switches the overcurrent protection circuit and the overheat protection circuit from the capacitive load driving mode to the normal mode.

8. The semiconductor device according to claim 1,
wherein in the normal mode, the overcurrent protection circuit performs one of:
a current restriction operation of restricting the output current to the overcurrent protection threshold value or less;
a hiccup operation of repeating the forced turning off and the restarting of the output switch each time the output current is increased to the overcurrent protection threshold value; and
an off-latch operation of continuing the forced turning off of the output switch when the output current is increased to the overcurrent protection threshold value.

9. The semiconductor device according to claim 1,
wherein the temperature to be monitored is a first temperature that is detected in a power element region including the output switch or a temperature difference between the first temperature and a second temperature that is detected in a region other than the power element region.

10. An electronic device comprising:
the semiconductor device according to claim 1; and
a load configured to receive supply of the output current from the semiconductor device.

11. A vehicle comprising: the electronic device according to claim 10.
